(19) United States
(12) Patent Application Publication
(10) Pub. No.: US 2007/0152283 A1
(43) Pub. Date: Jul. 5, 2007

(54) SEMICONDUCTOR DEVICE AND METHOD OF MANUFACTURING THE SAME

(75) Inventors: Hion-suck BAIK, Cheonan-si (KR); Eun-ha LEE, Seoul (KR); Hyung-suk JUNG, Suwon-si (KR); Sung-kee HAN, Seongnam-si (KR); Min-ho YANG, Suwon-si (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD., Suwon-si (KR)

(21) Appl. No.: 11/551,994

(22) Filed: Oct. 23, 2006

(30) Foreign Application Priority Data
Jan. 3, 2006 (KR) 10-2006-0000718

(51) Int. Cl. H01L 29/94; H01L 21/3205

(52) U.S. Cl. 257/411; 257/412; 438/585; 257/E29.128

(57) ABSTRACT

A semiconductor device and a manufacturing method thereof for preventing gate electrode degradation and gate current leakage. The semiconductor device includes a gate insulating layer including an H-k (high dielectric) material on a semiconductor substrate, a barrier metal layer including a metal alloy on the gate insulating layer, and a gate electrode layer formed on the barrier metal layer. Illustratively, the barrier metal layer includes at least one of TaAlN (tantalum aluminum nitride) or TiAlN (titanium aluminum nitride). The barrier metal layer can include an oxidation-resistant material so that oxidation of the barrier metal layer is prevented during a subsequent annealing of the semiconductor device in an oxygen atmosphere. Thus, degradation of a gate electrode is prevented, and gate current leakage due to degradation of the gate electrode is prevented.

This application claims priority to Korean Patent Application No. 2006-718, filed Jan. 3, 2006 in the Korean Intellectual Property Office, and all the benefits accruing therefrom under 35 U.S.C. §119(a), the disclosure of which is incorporated herein by reference in its entirety.

### BACKGROUND OF THE INVENTION

1. Field of the Invention

The present invention relates to a semiconductor device and a manufacturing method thereof, and more particularly, to a semiconductor device for preventing gate electrode degradation and gate current leakage, and a manufacturing method thereof.

2. Description of the Related Art

Metal-oxide semiconductor field-effect transistors (MOSFETs) including gate insulating layers and gate electrode layers sequentially stacked on semiconductor substrates have been used as semiconductor devices so as to satisfy demands for high-speed operation and low power consumption.

In particular, the gate insulating layers of MOSFETs have been made thin so as to provide semiconductor devices with high integration, high performance, and capable of operating at low voltage.

In general, gate insulating layers are formed of SiO₂. However, in cases where the SiO₂ gate insulating layers are thin, a tunnel current is generated by electrons or holes directly tunneling through the gate insulating layers, thereby increasing a gate leakage current. Accordingly, as the thickness of the gate insulating layer is reduced, a critical thickness is approached which represents a technical limitation of using SiO₂ as a gate insulating layer in a thin semiconductor device.

To overcome this technical limitation, a gate insulating layer may be formed using a high dielectric material, as shown in FIG. 13.

A gate electrode of a semiconductor device includes the gate insulating layer (hereinafter referred to as an H-k layer 12) formed of a high dielectric material on a semiconductor substrate 10. The gate electrode also includes a gate electrode layer 14 formed of a polysilicon on the H-k layer 12, and a barrier metal layer 13 formed between the H-k layer 12 and the gate electrode layer 14. The barrier metal layer 13 prevents migration of dopant from the gate electrode layer 14.

In cases where the gate electrode is formed using the H-k layer 12 as described above, the resulting gate insulating layer may be thicker than a gate insulating layer formed using SiO₂, thereby reducing or eliminating gate leakage current, and permitting the manufacture of thin semiconductor devices.

In general, the H-k layer 12 may be formed of a tantalum oxide layer (Ta₂O₅), a titanium oxide layer (TiO₂), a hafnium oxide layer (HfO₂), a zirconium oxide layer (ZrO₂), a lanthanum oxide layer (La₂O₃), or the like. The barrier metal layer 13 may be formed of a tantalum nitride (TaN), a titanium nitride (TiN), or the like. Dopant density of the gate electrode layer 14 must be uniformly maintained to achieve high performance for the gate electrode having the above-described structure. The barrier metal layer 13 is necessary in order to maintain uniform dopant density for the gate electrode layer 14. The semiconductor device undergoes one or more subsequent annealing processes in an oxygen atmosphere, such as a gate poly oxidation (GPOX) process performed at a high temperature of about 800° C., or a Co silicidation process performed at a high temperature of about 850° C. or the like.

Considering position b (FIG. 15) in conjunction with barrier metal layer 13 and H-k layer 12 (FIG. 14), if the barrier metal layer 13 is formed of a material such as TaN or TiN, this material reacts with the H-k layer 12. Thus, elements are transposed between the barrier metal layer 13 and the H-k layer 12 when a subsequent high temperature annealing process is performed in an oxygen atmosphere. As a result, the barrier metal layer 13 is oxidized and thus degraded.

### SUMMARY OF THE INVENTION

The present invention addresses the above-mentioned and other problems and disadvantages occurring in the art. One aspect of the present invention includes providing a semiconductor device that prevents deterioration of a gate electrode and that reduces or eliminates a gate leakage current. Another aspect includes a method of manufacturing the semiconductor device.

In accordance with another exemplary embodiment, a semiconductor device includes: a semiconductor substrate; a gate insulating layer including an H-k (high dielectric) material on the semiconductor substrate; a barrier metal layer including a metal alloy on the gate insulating layer; and a gate electrode layer formed on the barrier metal layer. In exemplary embodiments, the metal alloy is an aluminum alloy. In exemplary embodiments, the barrier metal layer may include at least one of TaAlN (tantalum aluminum nitride) and TiAlN (titanium aluminum nitride). In exemplary embodiments, the barrier metal layer may have a thickness between about 20Δ and 50Δ.

In exemplary embodiments, the semiconductor device may further include: an isolation layer, a low density dopant area, a gate spacer, and a high density dopant area. The gate insulating layer, the barrier metal layer, and the gate electrode layer may form a gate electrode of the semiconductor device, and the low and high density dopant areas may form drain and source electrodes for the semiconductor device.

In exemplary embodiments, the gate insulating layer may include at least one of a tantalum oxide layer (Ta₂O₅), a titanium oxide layer (TiO₂), a hafnium oxide layer (HfO₂), a zirconium oxide layer (ZrO₂), a lanthanum oxide layer (La₂O₃), an aluminum oxide layer (Al₂O₃), a yttrium oxide layer (Y₂O₃), a niobium oxide layer (Nb₂O₅), a cesium oxide layer (CeO₂), an iridium oxide layer (IrO₂), an indium oxide layer (InO₃), a BST layer ((Ba,Sr)TiO₃), or a PZT layer ((Pb,Zr)TiO₃).

In exemplary embodiments, the gate insulating layer may have a thickness between about 20Δ and 40Δ.

In exemplary embodiments, the gate electrode layer may include a polysilicon.

According to another aspect of the present invention, a method of manufacturing a semiconductor device includes: forming a gate insulating layer including an H-k material on a semiconductor substrate; forming a barrier metal layer including an aluminum alloy on the gate insulating layer; and forming a gate electrode layer on the barrier metal layer.

The barrier metal layer may be formed using a CVD (chemical vapor deposition) method including a MOCVD (metal organic CVD) method and an ALD (atomic layer deposition) method, or may be formed using a PVD (physical vapor deposition) method including sputtering.

In exemplary embodiments, the barrier metal layer may include at least one of TaAlN or TiAlN.

In exemplary embodiments, the forming of the barrier metal layer of the aluminum alloy on the gate insulating layer may include: spraying a mixture of Ta or Ti and an Al ligand (illustratively, Al[(CH₃)₃]) on the semiconductor substrate on which the gate insulating layer is formed to form a TaAl or TiAl layer; and spraying an ammonia gas (NH₃) on the semiconductor substrate on which the mixture is sprayed to form a TaAlN or TiAlN layer.

In exemplary embodiments, the forming of the barrier metal layer of the aluminum alloy on the gate insulating layer may include: spraying a mixture of Ta or Ti and an ammonia gas (NH₃) on the semiconductor substrate on which the gate insulating layer is formed to form a TaN or TiN layer; spraying a mixture of an Al ligand (illustratively, Al[(CH₃)₃]) and an ammonia gas (NH₃) on the TaN or TiN layer to form an AlN layer; spraying a mixture of Ta or Ti and an ammonia gas (NH₃) on the AlN layer to form a TaN or TiN layer; and annealing the semiconductor substrate to form a TaAlN or TiAlN layer.

In exemplary embodiments, a thickness of the barrier metal layer may be within a range between about 20Δ and 50Δ.

In exemplary embodiments, the gate insulating layer may be formed using a CVD method including a MOCVD method or an ALD method.

In exemplary embodiments, the gate insulating layer may include at least one of a tantalum oxide layer (Ta₂O₅), a titanium oxide layer (TiO₂), a hafnium oxide layer (HfO₂), a zirconium oxide layer (ZrO₂), a lanthanum oxide layer (La₂O₃), an aluminum oxide layer (Al₂O₃), a yttrium oxide layer (Y₂O₃), a niobium oxide layer (Nb₂O₅), a cesium oxide layer (CeO₂), an iridium oxide layer (IrO₂), an indium oxide layer (InO₃), a BST layer ((Ba,Sr)TiO₃), or a PZT layer ((Pb,Zr)TiO₃).

In exemplary embodiments, a thickness of the gate insulating layer may be within a range between about 20Δ and 40Δ.

In accordance with further exemplary embodiments, the method of manufacturing the semiconductor device may further include: patterning the gate insulating layer, the barrier metal layer, and the gate electrode layer; forming a spacer insulating layer covering sidewalls of the patterned gate insulating layer, barrier metal layer, and gate electrode layer; and etching the spacer insulating layer to form a gate spacer.

### BRIEF DESCRIPTION OF THE DRAWINGS

The above and other aspects and features of the present invention will become more apparent and more readily appreciated from the following detailed description taken in conjunction with the accompanying drawings, in which:

FIG. 1 is a cross-sectional view of a portion of a semiconductor device according to an exemplary embodiment of the present invention;

FIG. 2 is a graph illustrating capacitance as a function of voltage for an exemplary material used to form the barrier metal layer of FIG. 1, thereby demonstrating an illustrative source of current leakage for the semiconductor device;

FIGS. 3 through 6 are cross-sectional views illustrating a semiconductor device manufactured according to a first exemplary embodiment of the present invention;

FIGS. 7 through 11 are cross-sectional views illustrating a semiconductor device manufactured according to a second exemplary embodiment of the present invention;

FIG. 12 is a view illustrating a state of a barrier metal layer of FIG. 7 having undergone an annealing process;

FIG. 13 is a cross-sectional view of a portion of a conventional semiconductor device compared with a semiconductor device constructed in accordance with an illustrative embodiment of the present invention;

FIG. 14 is an enlarged view of an area A shown in FIG. 13; and

FIG. 15 is a graph illustrating a composition state of area I-I′ of FIG. 14.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in detail with reference to the accompanying drawings.

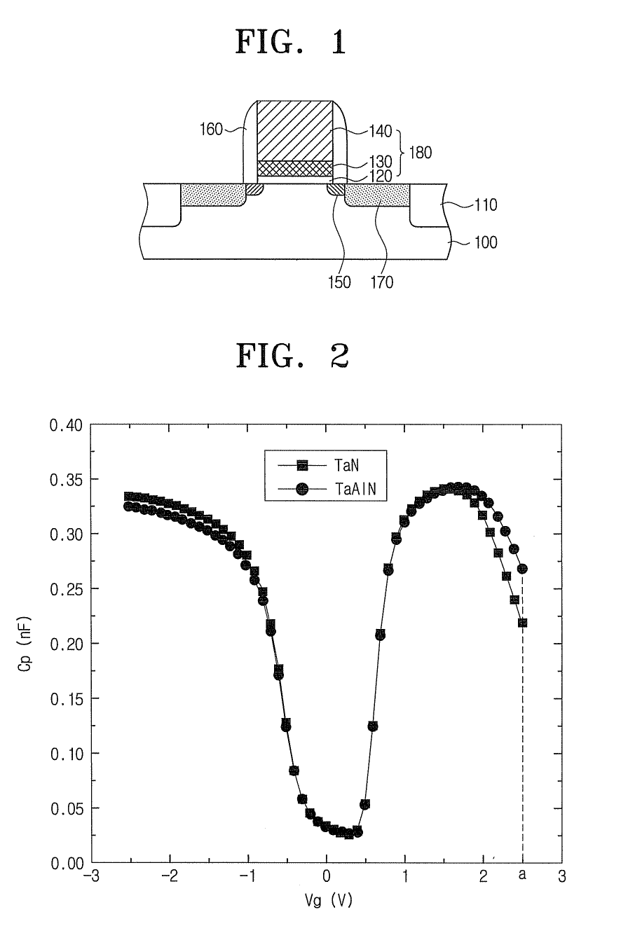

FIG. 1 is a cross-sectional view of a portion of a semiconductor device according to an exemplary embodiment of the present invention, and FIG. 2 is a graph illustrating capacitance as a function of voltage for an exemplary material used to form the barrier metal layer 130 of FIG. 1, thereby demonstrating a source of current leakage for the semiconductor device. Referring to FIG. 1, the semiconductor device includes a semiconductor substrate 100, an isolation layer 110, a gate insulating layer 120, a barrier metal layer 130, and a gate electrode layer 140. The semiconductor device further includes a low density dopant area 150, a gate spacer 160, and a high density dopant area 170. The isolation layer 110 is formed in a predetermined area of the semiconductor substrate 100 and defines an active area of the semiconductor device. A gate pattern 180 crossing the isolation layer 110 is formed above the active area. The gate spacer 160 is formed on a sidewall of the gate pattern 180, and the low density dopant area 150 is formed in an area of the active area of the semiconductor device defined by the isolation layer 110, the area being around the gate pattern 180. The high density dopant area 170 is formed in a portion of the active area of the semiconductor device around the gate spacer 160. The high density dopant area 170 is relatively denser and deeper than the low density dopant area 150 and serves as a source and drain for the semiconductor device. The gate pattern 180 includes the gate insulating layer 120, the barrier metal layer 130, and the gate electrode layer 140.

The gate insulating layer 120 is formed of an H-k material adjacent to an upper surface of the semiconductor substrate 100 so as to insulate the gate pattern 180 from the semiconductor substrate 100. Pursuant to exemplary embodiments, the gate insulating layer 120 may include at least one of a tantalum oxide layer (Ta₂O₅), a titanium oxide layer (TiO₂), a hafnium oxide layer (HfO₂), a zirconium oxide layer (ZrO₂), a lanthanum oxide layer (La₂O₃), an aluminum oxide layer (Al₂O₃), a niobium oxide layer (Nb₂O₅), a cesium oxide layer (CeO₂), an iridium oxide layer (IrO₂), a yttrium oxide layer (Y₂O₃), an indium oxide layer (InO₃), a BST layer ((Ba,Sr)TiO₃), a PZT ((Pb,Zr)TiO₃), or the like. Here, a thickness of the gate insulating layer 120 may be within a range between about 20Δ and 40Δ.

The barrier metal layer 130 is adjacently formed of an oxidation-resistant material on the gate insulating layer 120 so as to uniformly maintain a dopant density of the gate electrode layer 140 and inhibit a reaction between the gate electrode layer 140 and the gate insulating layer 120.The barrier metal layer 130 may include a metal alloy, illustratively an aluminum alloy, so as to maximize an oxidation-resistant property. Alternatively, the barrier metal layer 130 may include a tantalum aluminum nitride (TaAlN) or a titanium aluminum nitride (TiAlN). In other words, the barrier metal layer 130 may be formed using an oxidation-resistant property of a metal alloy so that, if a subsequent annealing process is performed, oxidation of the barrier metal layer 130 is prevented.

If the barrier metal layer 130 includes TaAlN or TiAlN, the barrier metal layer 130 can be prevented from being oxidized as described in the prior art. Thus, a gate current leakage phenomenon caused by the barrier metal layer 130 can be prevented. This will be further clearly described with reference to FIG. 2.

Referring to FIG. 2, when the barrier metal layer 130 includes a tantalum nitride (TaN), a capacitance Cp of the gate pattern 180 is smaller than when the barrier metal layer 130 is formed of TaAlN. This means that TaN is oxidized during a subsequent annealing process for manufacturing the semiconductor device and thus degraded. Thus, although the same gate voltage Vg is applied to the gate electrode, i.e., the gate pattern 180, as shown with point a, an intensity of a leakage current may vary with a material of which the barrier metal layer 130 is formed or an oxidation degree of the material. Here, a thickness of the barrier metal layer 130 may be within a range between about 20Δ and 50Δ.

Referring to FIG. 1 again, the gate electrode layer 140 may be adjacently formed of a polysilicon on the barrier metal layer 130. The gate electrode layer 140 is supplied with the gate voltage Vg so as to activate the semiconductor device.

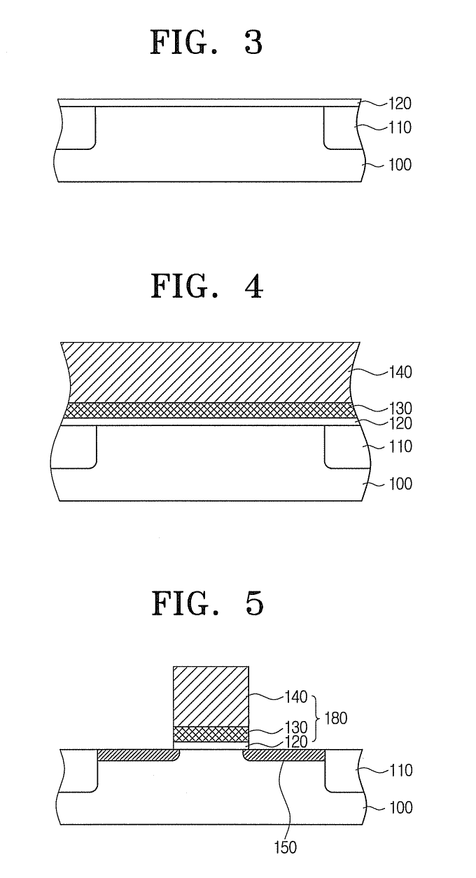

FIGS. 3 through 6 are cross-sectional views illustrating a semiconductor device manufactured according to a first exemplary embodiment of the present invention.

Referring to FIG. 3, an isolation layer 110 is formed in a predetermined area of a semiconductor substrate 100 so as to define an active area. A gate insulating layer 120 includes an H-k material on a surface of the semiconductor substrate 100 including the isolation layer 110. The isolation layer 110 may be formed using a general trench isolation technique to produce a highly integrated semiconductor device. Also, a thermal oxide layer (not shown) and a silicon nitride liner (not shown) may be included between the isolation layer 110 and the semiconductor substrate 100.

The H-k material which the gate insulating layer 120 includes may be at least one of a tantalum oxide layer (Ta₂O₅), a titanium oxide layer (TiO₂), a hafnium oxide layer (HfO₂), a zirconium oxide layer (ZrO₂), a lanthanum oxide layer (La₂O₃), an aluminum oxide layer (Al₂O₃), a niobium oxide layer (Nb₂O₅), a cesium oxide layer (CeO₂), an iridium oxide layer (IrO₂), a yttrium oxide layer (Y₂O₃), an indium oxide layer (InO₃), a BST layer ((Ba,Sr)TiO₃), a PZT ((Pb,Zr)TiO₃), or the like. A thickness of the gate insulating layer 120 may be within a range between about 20Δ and 40Δ.

The gate insulating layer 120 may be formed of an H-k material using a chemical vapor deposition (CVD) method. Here, the CVD method includes a metal organic CVD (MOCVD) method or an atomic layer deposition (ALD) method. The CVD method is well known to those having ordinary skill in the relevant art, and thus its detailed description will be omitted.

Referring to FIG. 4, a barrier metal layer 130 and a gate electrode layer 140 may be sequentially formed on the gate insulating layer 120 shown in FIG. 3.The barrier metal layer 130 may include an aluminum alloy. According to illustrative embodiments, the aluminum alloy may be at least one of TaAlN or TiAlN. The barrier metal layer 130 may be formed using the CVD method including the MOCVD method or the ALD method. According to illustrative embodiments, the barrier layer 130 may be formed using the ALD method of growing a layer having a very uniform thickness and composition.

The barrier metal layer 130 may be formed using any of the following processes in conjunction with the CVD method. For example, the barrier metal layer 130 may be formed as follows: spraying a mixture of a material such as Ta or Ti and an aluminum ligand (illustratively, Al[(CH₃)₃] which is trimethyl aluminum) on the semiconductor substrate 100 on which the gate insulating layer 120 is formed to provide TaAl or TiAl; and spraying an ammonia gas NH₃ on the semiconductor substrate 100 on which TaAl or TiAl is formed to provide TiAlN.

Alternatively or additionally, the barrier metal layer 130 may be formed on the semiconductor substrate 100 on which the gate insulating layer 120 is formed, using a physical vapor deposition (PVD) method such as sputtering. The barrier metal layer 130 may be formed to a thickness between 20Δ and 50Δ on the gate insulating layer 120 using the CVD method or the PVD method. The gate electrode layer 140 may be formed of a polysilicon on the barrier metal layer 130 using the CVD method or the PVD method.

Referring to FIG. 5, the gate insulating layer 120, the barrier metal layer 130, and the gate electrode layer 140 on the semiconductor substrate 100 may be sequentially patterned to form a gate pattern 180. The gate pattern 180 may be formed using an etching process. Here, the etching process may use an anisotropic etching method with a photoresist pattern as an etching mask. The gate pattern 180 is used as an ion implantation mask to perform a low density ion implantation process so as to form a low density dopant area 150 around the gate pattern 180.

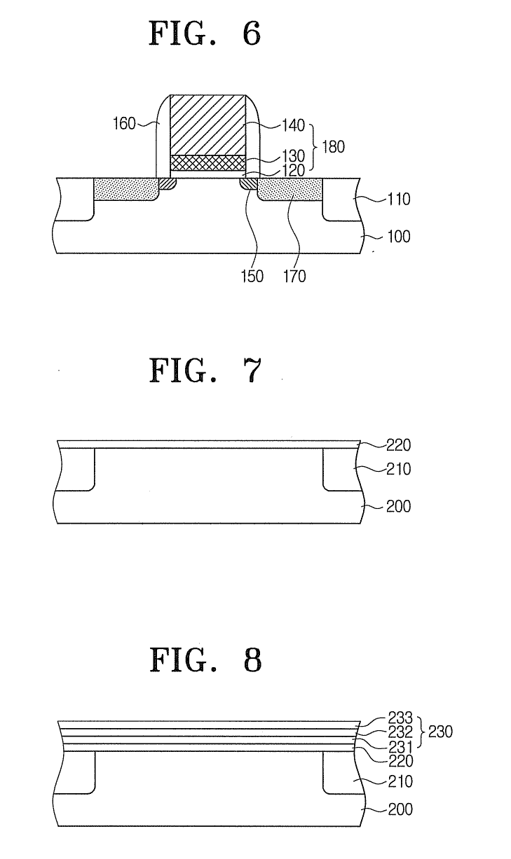

Referring to FIG. 6, a gate space 160 is formed on a sidewall of the gate pattern 180 shown in FIG. 5. A spacer insulating layer (not shown) may be formed on an entire surface of the semiconductor substrate 100 including the low density dopant area 150 and then anisotropically etched so as to form the gate spacer 160. The gate spacer 160 is used as a mask to perform a high density ion implantation process so that a high density dopant area 170 is formed in an area of the semiconductor substrate 100 around the gate spacer 160.

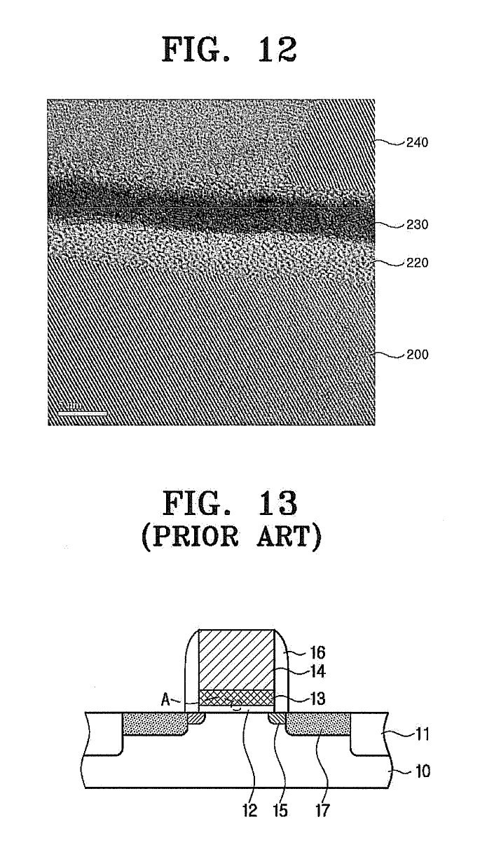

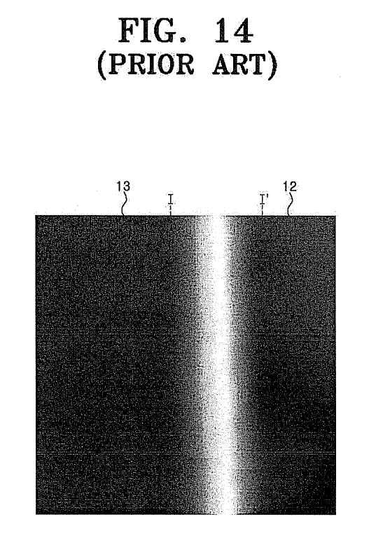

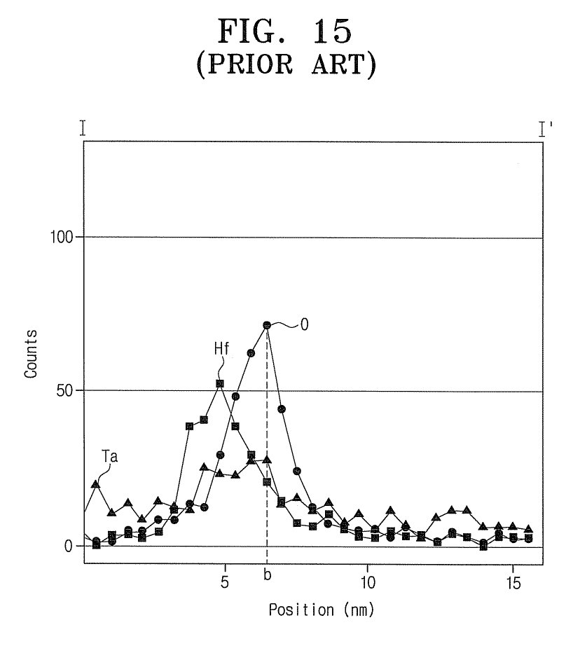

FIGS. 7 through 11 are cross-sectional views illustrating a semiconductor device manufactured according to a second exemplary embodiment of the present invention, and FIG. 12 is a view illustrating a state of a barrier metal layer 230 of FIG. 7 having undergone an annealing process. Referring to FIG. 7, an isolation layer 210 is formed in a predetermined area of a semiconductor substrate 200 to define an active area. A gate insulating layer 220 includes an H-k material on an entire surface of the semiconductor substrate 200 including the isolation layer 210. Here, the isolation layer 210 and the gate insulating layer 220 respectively include the same materials as those of which the isolation layer 110 and the gate insulating layer 120 shown in FIG. 3 are formed, illustratively using the same methods as those by which the isolation layer 110 and the gate insulating layer 120 are formed. Thus, detailed descriptions of the isolation layer 210 and the gate insulating layer 220 will be omitted.

Referring to FIG. 8, a barrier metal layer 230 is formed on the gate insulating layer 220 shown in FIG. 7.In exemplary embodiments, the barrier metal layer 230 may include an aluminum alloy. Illustratively, the aluminum alloy may be at least one of TaAlN or TiAlN. The barrier metal layer 230 may be formed using a CVD method including a MOCVD method or an ALD method. Illustratively, the barrier metal layer 230 may be formed using the ALD method of growing a layer, thus providing a layer having a very uniform thickness and composition.

In exemplary embodiments, the barrier metal layer 230 may be formed using any of the following processes in conjunction with the CVD method:For example, the barrier metal layer 230 may be formed as follows: spraying a mixture of a material such as Ta or Ti and an ammonia gas(NH₃) on the semiconductor substrate 200 on which the gate insulating layer 220 is formed to form a TaN or TiN layer 231; spraying a mixture of an aluminum ligand (such as Al[(CH₃)₃] which is trimethyl aluminum) and an ammonia gas (NH₃) on the semiconductor substrate 200 on which the TaN or TiN layer 231 is formed to form an AlN layer 232; and spraying a mixture of a material such as Ta or Ti and an ammonia gas (NH₃) on the semiconductor substrate 200 on which the AlN layer 232 is formed to form a TaN or TiN layer 233.The barrier metal layer 230 having such a stack structure is formed of a single layer of TaAlN or TiAlN due to a transposition of atom combinations in the deposition of a poly silicon performed at a high temperature as shown in FIG. 12.

In exemplary embodiments, the TaN or TiN layers 231 and 233 and the AlN layer 232 of the barrier metal layer 230 having the stack structure may be formed using the ALD method or may be formed using various methods including the PVD method such as sputtering or the like. Here, the barrier metal layer 230 may determine thicknesses of the TaN or TiN layers 231 and 233 and the AlN layer 232 so that the TaN or TiN layers 231 and 233 and the AlN layer 232 are formed to the thickness between about 20A and 50A on the gate insulating layer 120 after a subsequent high temperature process.

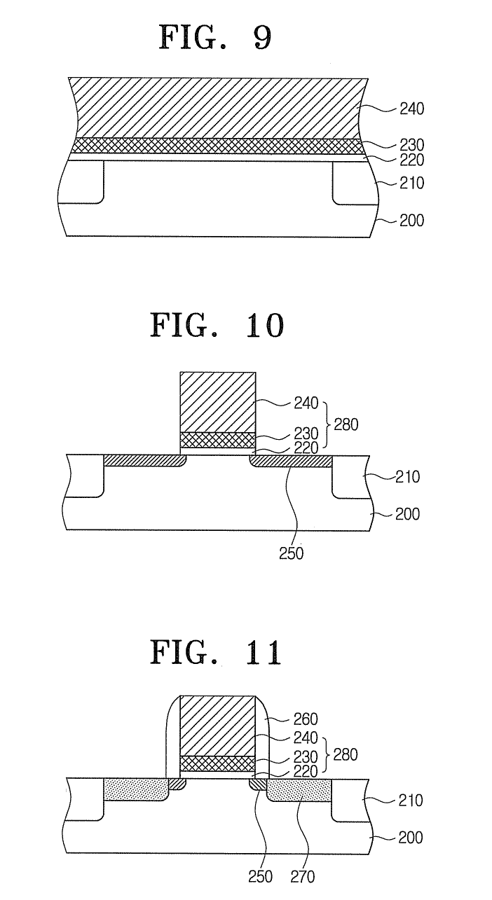

Referring to FIG. 9, a gate electrode layer 240 is formed of a polysilicon on the barrier metal layer 230 using the CVD method or the PVD method.

Referring to FIGS. 10 and 11, the gate insulating layer 220, the barrier metal layer 230, and the gate electrode layer 240 are sequentially patterned to form a gate pattern 280, and a gate spacer 260 is formed on a sidewall of the gate pattern 280.Illustrafively, the gate pattern 280 and the gate spacer 260 are formed using substantially the same methods as those by which the gate pattern 180 and the gate spacer 160 shown in FIG. 6 are formed, and thus detailed descriptions thereof will be omitted.

If a semiconductor device is formed using any of the above-described methods, oxidation of the barrier metal layer 130 or 230 is prevented during any subsequent annealing process used to manufacture the semiconductor device. Degradation of the semiconductor device due to oxidation thereof is prevented.

As described above, according to embodiments of the present invention, a gate insulating layer can be formed of an H-k material so as to manufacture a thin semiconductor device. Also, a barrier metal layer inhibiting a reaction between the gate insulating layer and a gate electrode layer can be formed of a high oxidation-resistant material so as to prevent a gate electrode from being degraded, i.e., oxidized. In addition, a gate leakage current caused by degradation of the gate electrode can be eliminated or reduced, so as to secure high-speed operation for the semiconductor device.

The foregoing embodiment and advantages are merely exemplary and are not to be construed as limiting the present invention. The present teaching can be readily applied to other types of devices. Also, the description of the embodiments of the present invention is intended to be illustrative, and not to limit the scope of the claims. Many alternatives, modifications, and variations will be apparent to those skilled in the art, and any such alternatives, modifications, and variations are deemed to fall within the scope of the invention.

What is claimed is:

1. A semiconductor device comprising:
a semiconductor substrate;
a gate insulating layer including an H-k (high dielectric) material on the semiconductor substrate;
a barrier metal layer including a metal alloy on the gate insulating layer; and
a gate electrode layer formed on the barrier metal layer.

2. The semiconductor device of claim 1, wherein the metal alloy is an aluminum alloy.

3. The semiconductor device of claim 1, wherein the barrier metal layer includes at least one of TaAlN (tantalum aluminum nitride) or TiAlN (titanium aluminum nitride).

4. The semiconductor device of claim 1, further comprising:
an isolation layer defining an active area of the semiconductor substrate;
a low density dopant area formed in a first portion of the active area proximate to the gate insulating layer, the barrier metal layer, and the gate electrode layer;
a gate spacer covering sidewalls of the gate insulating layer, the barrier metal layer, and the gate electrode layer; and
a high density dopant area formed in a second portion of the active area proimate to the gate spacer.

5. The semiconductor device of claim 4, wherein the gate insulating layer, the barrier metal layer, and the gate electrode layer form a gate electrode of the semiconductor device, and at least one of: (a) the low density dopant area, or (b) the high density dopant area, are used to form drain and source electrodes for the semiconductor device.

6. The semiconductor device of claim 1, wherein a thickness of the barrier metal layer is within a range between about 20Δ and 50Δ.

7. The semiconductor device of claim 1, wherein the gate insulating layer includes an oxide layer.

8. The semiconductor device of claim 7, wherein the gate insulating layer includes at least one of tantalum oxide (Ta₂O₅), titanium oxide (TiO₂), hafnium oxide (HfO₂), zirconium oxide (ZrO₂), lanthanum oxide (La₂O₃), aluminum oxide (Al₂O₃), yttrium oxide (Y₂O₃), niobium oxide (Nb₂O₅), cesium oxide (CeO₂), iridium oxide (IrO₂), indium oxide (InO₃), BST ((Ba,Sr)TiO₃), or PZT ((Pb,Zr)TiO₃).

9. The semiconductor device of claim 1, wherein a thickness of the gate insulating layer is within a range between about 20Δ and 40Δ.

10. The semiconductor device of claim 1, wherein the gate electrode layer includes a polysilicon.

11. A method of manufacturing a semiconductor device, comprising:
forming a gate insulating layer including an H-k material on a semiconductor substrate;
forming a barrier metal layer including a metal alloy on the gate insulating layer; and
forming a gate electrode layer on the barrier metal layer.

12. The method of claim 11 wherein the metal alloy is an aluminum alloy.

13. The method of claim 12, wherein the barrier metal layer is formed using a CVD (chemical vapor deposition) method comprising at least one of a MOCVD (metal organic CVD) method or an ALD (atomic layer deposition) method.

14. The method of claim 12, wherein the barrier metal layer is formed using a PVD (physical vapor deposition) method comprising sputtering.

15. The method of claim 12, wherein the barrier metal layer includes at least one of TaAlN or TiAlN.

16. The method of claim 12, wherein the forming of the barrier metal layer including the aluminum alloy on the gate insulating layer comprises:
spraying a mixture of Ta or Ti and an Al ligand on the semiconductor substrate on which the gate insulating layer is formed to form a layer including TaAl or TiAl; and
spraying an ammonia gas (NH₃) on the semiconductor substrate on which the mixture is sprayed to form a layer including TaAlN or TiAlN.

17. The method of claim 16 wherein the Al ligand comprises Al[(CH₃)₃].

18. The method of claim 12, wherein the forming of the barrier metal layer including the aluminum alloy on the gate insulating layer comprises:
spraying a mixture of Ta or Ti and an ammonia gas (NH₃) on the semiconductor substrate on which the gate insulating layer is formed to form a layer including TaN or TiN;
spraying a mixture of an Al ligand and an ammonia gas (NH₃) on the TaN or TiN layer to form a layer including AlN;
spraying a mixture of Ta or Ti and an ammonia gas (NH₃) on the layer including AlN to form a layer including TaN or TiN; and
annealing the semiconductor substrate to form a layer including TaAlN or TiAlN.

19. The method of claim 18 wherein the Al ligand comprises Al[(CH₃)₃].

20. The method of claim 12, wherein a thickness of the barrier metal layer is within a range between about 20Δ and 50Δ.

21. The method of claim 12, wherein the gate insulating layer is formed using a CVD method comprising at least one of a MOCVD method or an ALD method.

22. The method of claim 12, wherein the gate insulating layer includes an oxide layer.

23. The method of claim 22, wherein the gate insulating layer includes at least one of tantalum oxide (Ta₂O₅), titanium oxide (TiO₂), hafnium oxide (HfO₂), zirconium oxide (ZrO₂), lanthanum oxide (La₂O₃), aluminum oxide (Al₂O₃), yttrium oxide (Y₂O₃), niobium oxide (Nb₂O₅), cesium oxide (CeO₂), iridium oxide (IrO₂), indium oxide (InO₃), BST ((Ba,Sr)TiO₃), or PZT ((Pb,Zr)TiO₃).

24. The method of claim 12, wherein a thickness of the gate insulating layer is within a range between about 20Δ and 40Δ.

25. The method of claim 12, further comprising:
patterning the gate insulating layer, the barrier metal layer, and the gate electrode layer;
forming a spacer insulating layer covering at least one sidewall of the patterned gate insulating layer, barrier metal layer, and gate electrode layer; and
etching the spacer insulating layer to form a gate spacer.
